(19) United States
(12) Patent Application Publication
(10) Pub. No.: US 2006/0261354 A1
(43) Pub. Date: Nov. 23, 2006

(54) Semiconductor light-emitting device

(76) Inventors: Yasuhide Okada, Yokohama-shi (JP); Takayoshi Fujii, Yokohama-shi (JP); Kazuo Horiuchi, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/430,966

(22) Filed: May 10, 2006

(30) Foreign Application Priority Data
May 20, 2005 (JP) 2005-148213

(51) Int. Cl. H01L 33/00

(52) U.S. Cl. 257/79

(57) ABSTRACT

A semiconductor light-emitting device includes a substrate having light transmission characteristics, a light emission layer on a surface side of the substrate, and which emits light when being energized, and a pair of electrodes to energize the light emission layer, wherein a surface of the substrate which is located opposite to the light emission layer is formed to include groove portion through which light generated from the light emission layer and then entering the substrate is emitted from the substrate.

### CROSS-REFERENCE TO RELATED APPLICATIONS

This application is based upon and claims the benefit of priority from prior Japanese Patent Application No. 2005-148213, filed May 20, 2005, the entire contents of which are incorporated herein by reference.

### BACKGROUND OF THE INVENTION

1. Field of the Invention

The present invention relates to a semiconductor light-emitting device in which light generated from a light emitting layer is emitted through a substrate.

2. Description of the Related Art

FIG. 11 is a vertical sectional view of a conventional semiconductor light-emitting device. As shown in FIG. 11, the semiconductor light-emitting device comprises a substrate 100 having light transmission characteristics, a multi-layer structure 104, a P electrode 105 and an N electrode 106.

The multi-layer structure 104 is provided on a surface of the substrate 100, and includes an N-type semiconductor layer 101, a light emission layer 102 and a P-type semiconductor layer 103. The P electrode 105 is provided on a surface of the multi-layer structure 104, and located opposite to the substrate 100 with respect to the multi-layer structure 104. The N electrode 106 is provided on the other surface of the substrate 100. In the semiconductor light-emitting device, when a voltage is applied between the P electrode 105 and the N electrode 106, light is generated from the light emission layer 102.

In the conventional semiconductor light-emitting device, the refractive index of the substrate 100 greatly differs from those of other regions adjacent to the substrate 100. Thus, the light generated from the light emission layer 102 repeatedly totally reflects within the substrate 100 (as indicated by arrows in FIG. 11, and travels a long distance within the substrate 100.

However, since the light absorption ratio of the substrate 100 is not zero, when the light travels a long distance in the substrate 100, it loses a large amount of energy, thus reducing the light emission efficiency (the ratio of light emitted from the substrate 100 to that entering the substrate 100). In order to solve this problem, a semiconductor light-emitting device is proposed in which the total reflection of light is reduced due to a specific shape of the substrate (as disclosed in, e.g., Jpn. Pat. Appln. KOKAI Publication No. 10-341035 and JPN PCT National Publication No. 2003-523635).

FIG. 12 is a vertical sectional view of a semiconductor light-emitting device disclosed in Jpn. Pat. Appln. KOKAI Publication No. 10-341035.

As shown in FIG. 12, the semiconductor light-emitting device comprises slanting surfaces 100a at side portions of the substrate 100, which slant with respect to the light emission layer 102 (not shown in FIG. 12). Thereby, the light generated from the light emission layer 102 is easily emitted from the substrate 100 (as shown by arrows in FIG. 12), thus increasing the light emission efficiency.

FIG. 13 is a vertical sectional view of a semiconductor light-emitting device disclosed in JPN PCT National Publication No. 2003-523635.

As shown in FIG. 13, in the semiconductor light-emitting device, substrates 100 are provided on both surfaces of the multi-layer structure 104. At side portions of the substrates 100, slanting surfaces 100b are provided to slant with respect to the light emission layer 102 (not shown in FIG. 13). Thereby, the light generated from the light emission layer 102 is easily emitted from the substrate 100 (as indicated by arrows in FIG. 13), thus improving the light emission efficiency.

However, in the semiconductor light-emitting device disclosed in JPN PCT National Publication No. 2003-523635, since the N electrode 106 is provided on an emission surface of one of the substrates 100, the light generated from the light emission layer 102 is totally reflected or absorbed by the N electrode 106, as a result of which the light emission efficiency lowers. In view of this point, in recent years, semiconductor light-emitting devices have been made in which the N electrode 106 is omitted from the emission surface of the substrate 100 (as disclosed in, e.g., Jpn. Pat. Appln. KOKAI Publication No. 2003-243708).

FIG. 14 is a vertical sectional view of a semiconductor light-emitting device disclosed in Jpn. Pat. Appln. KOKAI Publication No. 2003-243708.

As shown in FIG. 14, in the semiconductor light-emitting device, the N electrode 106 is provided on the N-type semiconductor layer 101, and located opposite to the substrate 100 with respect to the N-type semiconductor layer 101. In a method of manufacturing such a semiconductor light-emitting device, first, the multi-layer structure 104 is formed on one of the surfaces of the substrate 100, which is other than the emission surface thereof. The multi-layer structure 104 comprises the N-type semiconductor layer 101, the light emission layer 102 and the P-type semiconductor layer 103. Then, parts of the P-type semiconductor layer 103 and light emission layer 102 are removed by etching or the like, thereby exposing part of the N-type semiconductor layer 101. On the exposed part of the N-type semiconductor layer, the N electrode 106 is formed. Thus, on the other surface of the substrate 100, no N electrode 106 is provided, i.e., an element which reflects or absorbs light is not provided, as a result of which the light emission efficiency is improved.

Furthermore, Jpn. Pat. Appln. KOKAI Publication No. 2003-243708 discloses a technique in which the P electrode is formed, and a number of P-type electrodes are each formed in the shape of an elongated strip, and are arranged on the P-type semiconductor layer. Such a technique enables current to effectively flow in the entire light emission layer, thus improving the light emission efficiency.

However, the technique disclosed in Jpn. Pat. Appln. KOKAI Publication No. 2003-243708 is intended to increase the amount of light emitted from the light emission layer; it is not intended to enable the light from the light emission layer to be efficiently emitted.

### BRIEF SUMMARY OF THE INVENTION

The present invention provides a semiconductor light-emitting device enabling light, which is generated from a light emission layer, and then enters a substrate, to be efficiently emitted from the substrate.

A semiconductor light-emitting device according to an aspect of the present invention comprises: a substrate having light transmission characteristics; a light emission layer on a surface side of the substrate, and which emits light when being energized; and a pair of electrodes to energize the light emission layer, wherein a surface of the substrate which is located opposite to the light emission layer is formed to include groove portion through which light generated from the light emission layer and then entering the substrate is emitted from the substrate.

According to the present invention, light generated from the light emission layer and entering the substrate can be efficiently emitted from the substrate.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a semiconductor light-emitting device according to an embodiment of the present invention.

FIG. 2 is a vertical sectional view of the semiconductor light-emitting device according to the embodiment.

FIG. 3 is a plan view of the semiconductor light-emitting device according to the embodiment.

FIG. 4 is a vertical sectional view of a first semiconductor light-emitting device not having groove portions or cut portions.

FIG. 5 is a vertical sectional view of a second semiconductor light-emitting device not having groove portions and having cut portions.

FIG. 6 is a vertical sectional view of the semiconductor light-emitting device according to the embodiment of the present invention.

FIG. 7 is a graph which indicates the light-emission efficiencies of the first semiconductor light-emitting device, the second light-emitting device and the light-emitting device according to the embodiment of the present invention.

FIG. 8 is a graph which indicates a relationship between light emission efficiency and the angles of slanting surfaces with respect to the normal to light emission layers in the embodiment.

FIG. 9 is a side view of a semiconductor light-emitting device provided as a modification of the embodiment.

FIG. 10 is a plan view of the semiconductor light-emitting device provided as the modification.

FIG. 11 is a vertical sectional view of a conventional semiconductor light-emitting device.

FIG. 12 is a vertical sectional view of a conventional semiconductor light-emitting device disclosed in Jpn. Pat. Appln. KOKAI Publication No. 10-341035.

FIG. 13 is a vertical sectional view of a conventional semiconductor light-emitting device disclosed in JPN PCT National Publication No. 2003-523635.

FIG. 14 is a vertical sectional view of a conventional semiconductor light-emitting device disclosed in Jpn. Pat. Appln. KOKAI Publication No. 2003-243708.

### DETAILED DESCRIPTION OF THE INVENTION

The structure of a semiconductor light-emitting device according to an embodiment of the present invention will be explained.

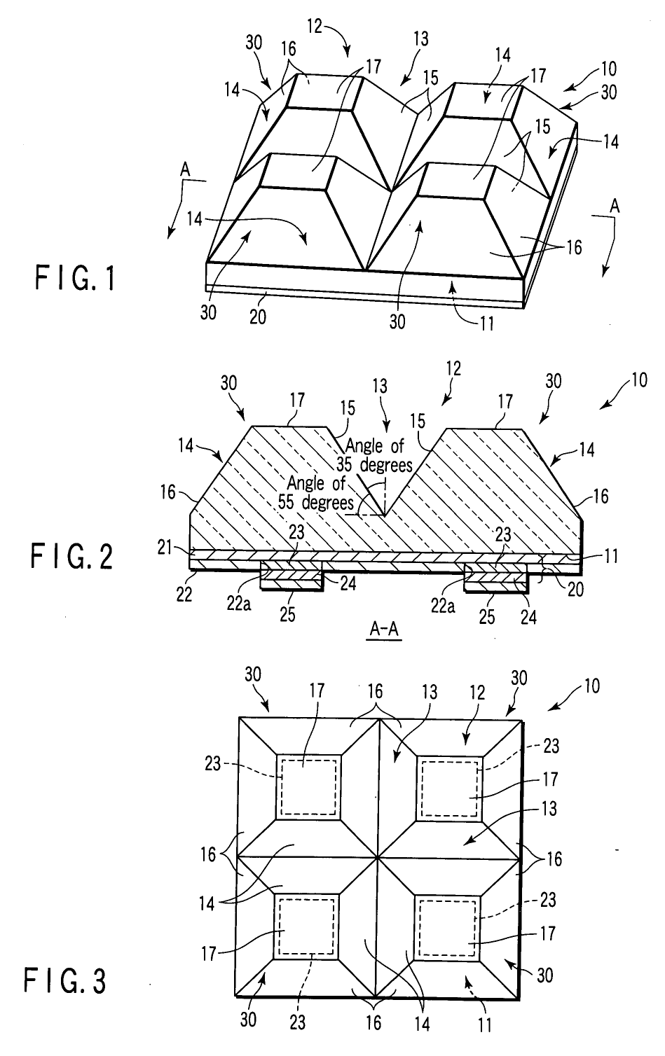

FIG. 1 is a perspective view of the semiconductor light-emitting device according to the embodiment of the present invention. FIG. 2 is a vertical sectional view of the semiconductor light-emitting device according to the embodiment. FIG. 3 is a plan view of the semiconductor light-emitting device according to the embodiment. It should be noted that FIG. 2 shows a vertical section taken along line A-A in FIG. 1.

As shown in FIGS. 1 to 3, the semiconductor light-emitting device comprises a substrate 10 having light transmission characteristics. The substrate 10 is formed of a monocrystal of, e.g., GaP (whose refractive index is 3.23). The substrate 10 is formed in the shape of a rectangular block having flat surfaces, which include two main surfaces parallel to each other. One of the main surfaces serves as an incidence surface 11 through which light from light emission layers 23 (which will be described later) enters the substrate 10, and the other serves as an emission surface 12 from which the light entering the substrate 10 is emitted. The size of the substrate 10 is set at approximately 800 μm×800 μm×230 μm.

In the emission surface 12 of the substrate 10, two groove portions 13 and four cut portions 14 are formed to cause light to be efficiently emitted from the substrate 10. Thereby, in the emission surface 12 of the substrate 10, four projection portions 30 are formed.

Each of the groove portions 13 comprises two slanting surfaces 15 which are slanted such that the distance between the two slanting surfaces 15 gradually increases in a direction away from the light emission layers 23. Each of the cut portions 14 comprises a slanting surface 16 which is slanted toward the center of the substrate 10 in the direction away from the light emission layers 23. At outermost portions of the projection portions 30, which are located farthest from the light emission layers 23, non-slanting surfaces 17 are formed continuous with the slanting surfaces 15 and 16 and in substantially parallel with the light emission layers 23.

It should be noted that the groove portions 13 and the cut portions 14 each have a depth of approximately 165 μm. The slanting surfaces 15 and 16 are at an angle of approximately 35° with respect to the normal to the light emission layers 23. In other words, the slanting surfaces 15 and 16 are at an angle of approximately 55° with respect to a plane parallel to the light emission layers 23.

At the incidence surface 11 of the substrate 10, a multi-layer structure 20 is provided. In the multi-layer structure 20, an N-type semiconductor layer 21 and a plurality of P-type semiconductor layers 24 are provided in this order from the substrate side. Junction portions between the N-type semiconductor layer 21 and the P-type semiconductor layers 24 function as the light emission layers 23.

With respect to the emission surface, the P-type semiconductor layers 24 are located on the side of the substrate 10 opposite to the incidence surface 11 within projection regions corresponding to the non-slanting surfaces 17, which do not overlap with the groove portions 13 and the cut portions 14 as viewed from the emission surface side. It should be noted that the light emission layers 23, as described above, are formed as the junction portions between the N-type semiconductor layer 21 and the P-type semiconductor layers 24. Also, with respect to the emission surface, the light emission layers 23, as well as the P-type semiconductor layers 24, are also located on the side of the substrate 10 opposite to the incidence surface 11 within the projection regions corresponding to the non-slanting surfaces 17.

It should be noted that the size of each of the light emission layers 23 is 155 μm×155 μm. The N-type semiconductor layer 21 and the P-type semiconductor layers 24 are formed of, e.g., InGaAlP (refractive index: 3.1 to 3.5).

An N electrode 22 is formed on that area of the N-type semiconductor layer 21, which is located opposite to the substrate 10 with respect to the N-type semiconductor layer 21, and which is other than the areas where the P-type semiconductor layers 24 are present. P electrodes 25 are formed on the P-type semiconductor layers 24, and located opposite to the substrate 10 with respect to the P-type semiconductor layers 24. That is, with respect to the emission surface, the P electrodes 25, as well as the P-type semiconductor layers 24, are located on the side of the substrate 10 opposite to the incidence surface 11 of the substrate 10 within the projection regions corresponding to the non-slanting surfaces 17.

In the above semiconductor light-emitting device, when a voltage is applied between the N electrodes 22 and the P electrodes 25, the light emission layers 23 are energized. Thereby, light is radiated in all directions from the entire light emission layers 23. The light from the light emission layers 23 enters the substrate 10 through the incidence surface 11 thereof. After traveling in various directions in the substrate 10, the light is emitted from the slanting surfaces 15, slanting surfaces 16 and non-slanting surfaces 17 which are formed at the emission surface 12 of the substrate 10.

In such a manner, the slanting surfaces 15, the slanting surfaces 16 and the non-slanting surfaces 17 are located opposite to the light emission layers 23. Thus, a large number of light components of the light radially emitted from the light emission layers 23 are incident at an angle smaller than the critical angle with respect to the emission surface 12 of the substrate 10. Thus, the ratio of light totally reflecting in the substrate 10 to the entire light generated from the light emission layers 23 lowers. As a result, the light entering the substrate 10 is efficiently emitted from the substrate 10.

The comparison between the above substrate and other substrates different in shape therefrom will be exaplained.

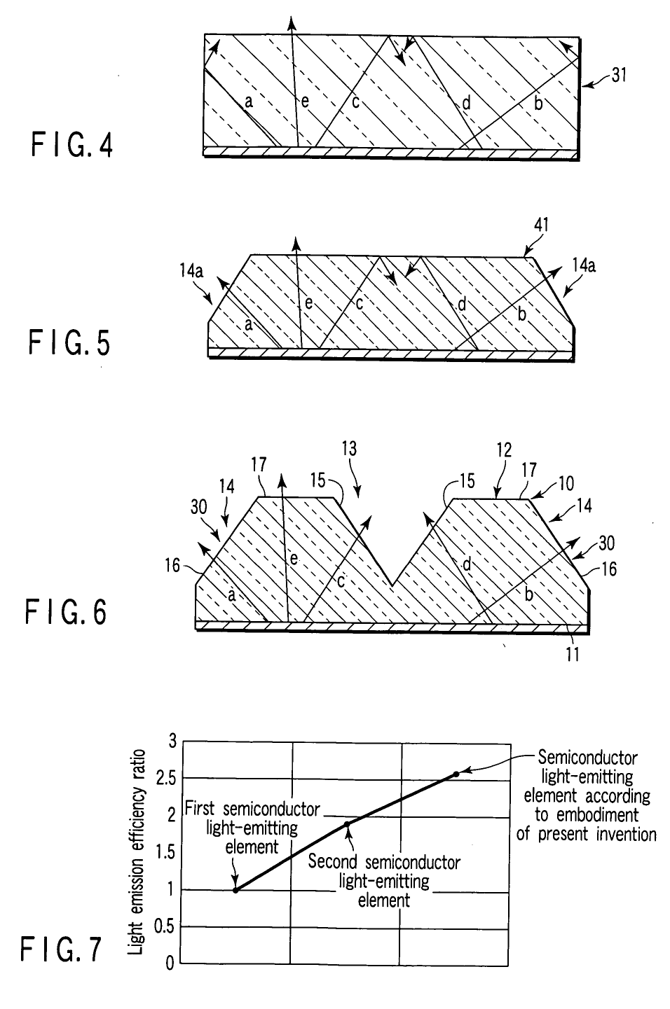

FIG. 4 is a vertical sectional view of a first semiconductor light-emitting device not having groove portions or cut portions. FIG. 5 is a vertical sectional view of a second semiconductor light-emitting device not having groove portions and having cut portions. FIG. 6 is a vertical sectional view of the semiconductor light-emitting device according to the embodiment of the present invention. In FIGS. 4 to 6, arrows “a” to “e” indicate movement of light from the light emission layers.

The first and second semiconductor light-emitting devices are enclosed by silicone resin (refractive index: 1.43). The size of each of the first and second semiconductor light-emitting devices is set to 800 μm×800 μm×230 μm. The size of each light emission layer of each of the first and second semiconductor light-emitting devices is set to 310 μm×310 μm, and each light-emitting layer is formed at substantially the center of the substrate.

In the first semiconductor light-emitting device, as shown in FIG. 4, a number of light components totally reflect within a substrate 31. In the second semiconductor light-emitting device, as shown in FIG. 5, the number of light components which totally reflect within a substrate 41 is reduced due to cut portions 14a; that is, the number of light components (indicated by arrows “a” and “b”) which are emitted from the substrate 41 without reflecting is increased. In other words, there are still light components which totally reflect within the substrate 41. On the other hand, in the semiconductor light-emitting device according to the embodiment, as shown in FIG. 6, the number of light components which totally reflect within the substrate 10 is further reduced due to the groove portions 13, and the light components (indicated by arrows c and d) which totally reflect in the second semiconductor light-emitting are also emitted from the substrate 10 without reflecting.

FIG. 7 is a graph which indicates the light-emission efficiencies of the first semiconductor light-emitting device, the second light-emitting device and the light-emitting device according to the embodiment of the present invention. In the graph, the vertical axis indicates the ratio of the emission efficiency of each of the second light-emitting device and the light-emitting device according to the embodiment of the present invention to that of the first light-emitting device.

As shown in FIG. 7, the light-emission efficiency of the semiconductor light-emitting device according to the present invention is far higher than those of the first and second light-emitting devices. It has been confirmed from this result that when the groove portions 13 and the cut portions 14 are formed at the emission surface 12 of the substrate 10, the light-emission efficiency is greatly increased.

The relationship between the light-emission efficiency and the angles of the slanting surfaces 15 and 16 will be explained.

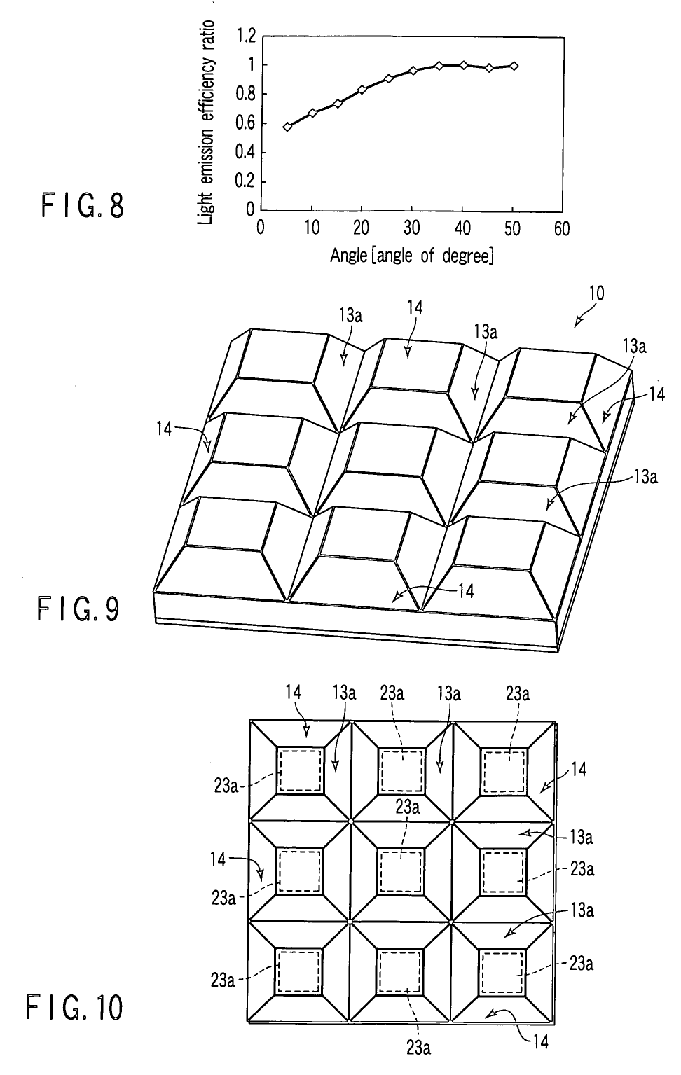

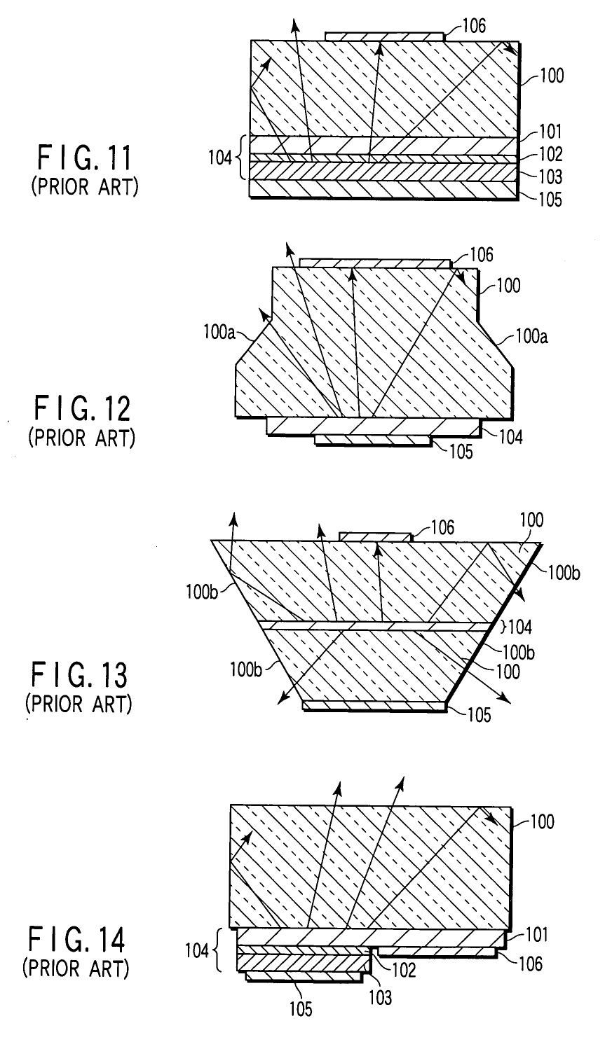

FIG. 8 is a graph which indicates a relationship between the light emission efficiency and the angles of the slanting surfaces 15 and 16 to the normal to the light emission layers 23 in the embodiment. The horizontal axis of the graph indicates the angle of each of the slanting surfaces 15 and 16, and the vertical axis of the graph indicates the ratio of the light emission efficiency measured when the slanting surfaces 15 and 16 slant at an angle other than 35° to the light emission efficiency measured when the angles of the slanting surfaces 15 and 16 are 35°.

As shown in FIG. 8, when the angles of the slanting surfaces 15 and 16 to the normal to the light emission layers 23 falls within the range of 20 to 50°, the light-emission efficiency is high. It should be noted that the angles of the slanting surfaces 15 and 16 to the normal to the light emission layers 23 correspond to the complements of the angles of surfaces 15 and 16 to the plane parallel to the light emission layers 23. Therefore, when the angles of the slanting surfaces 15 and 16 to the normal to the light emission layers 23 falls within the range of 40 to 70° (their complementary angles fall within the range of 20 to 50°), the light-emission efficiency is high.

In such a manner, in the embodiment, in the substrate having the above size, it has been confirmed that when the angles of the slanting surfaces 15 and 16 are 35° (i.e., their angles to the normal to the light emission layers are approximately 55°), the light-emission efficiency is high. However, since the above comparison is based on the size of the substrate in the embodiment, it can be considered that the above range of the angles slightly changes if the size of the substrate is changed.

The semiconductor light-emitting device according to the above embodiment has the following advantages:

The semiconductor light-emitting device according to the embodiment, as described above, includes the groove portions 13 and the cut portions 14. The groove portions 13 and the cut portions 14 comprise the slanting surfaces 15 and 16, respectively, which are at an angle of 35° with respect to the normal to the light emission layers 23 (at angle of 55° with respect to the plane parallel to the light emission layers 23). Furthermore, the light emission layers 23 are located in positions displaced from projection regions corresponding to the groove portions 13 and the cut portions 14.

Therefore, a number of light components of light emitted from the light emission layers 23 are incident on the slanting surfaces 15 and 16 provided at the emission surface 12 of the substrate 10, at an angle smaller than the critical angle, thus reducing the amount of light reflected in the substrate 10, and improving the light emission efficiency.

Moreover, as also described above, the slanting surfaces 15 and 16 are at an angle of approximately 35° with respect to the normal to the light emission layers 23. Thus, when the groove portions 13 and the cut portions 14 are formed, it is not necessary to use a dicing blade having a relatively large angle. It suffices that a dicing blade having an angle of 70° is applied. Thus, the groove portions 13 and the cut portions 14 are easily formed.

The present invention is not limited to the above embodiment. For example, as shown in FIGS. 9 and 10, the emission surface 12 of the substrate 10 may be formed to have two groove portions 13a extending in a column direction and two groove portions 13a extending in a row direction. In this case also, the light emission layers 23a are located in positions displaced from projection regions corresponding to the groove portions 13a and the cut portions 14.

Further, in the embodiment, the groove portions 13 are V-shaped; however, they may be formed by combining curved surfaces and slanting surfaces, or by combining slanting surfaces inclined at different angles.

Furthermore, in the embodiment, the substrate 10 is formed of GaP; however, it may be formed of another material. Also, in the embodiment, the N-type semiconductor layer 21 and the P-type semiconductor layers 24 are formed of InGaAlP; however, they may be formed of any material as long as it is material applicable as that of a semiconductor layer.

The present invention is not limited to the above embodiment. When it is put to practical use, structural elements can be modified without departing from the subject matter of the present invention. Furthermore, various inventions can be made by appropriately combining structural elements disclosed with respect to the embodiment. For example, some of all the above-mentioned structural elements in the embodiment may be omitted. In addition, structural elements in different embodiments may be appropriately combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor light-emitting device comprising:
a substrate having light transmission characteristics;
a light emission layer on a surface side of the substrate, and which emits light when being energized; and
a pair of electrodes to energize the light emission layer,
wherein a surface of the substrate which is located opposite to the light emission layer is formed to include groove portion through which light generated from the light emission layer and then entering the substrate is emitted from the substrate.

2. The semiconductor light-emitting device according to claim 1, wherein outer peripheral portion of the surface of the substrate is formed to include cut portion through which light generated from the light emission layer and then entering the substrate is emitted from the substrate.

3. The semiconductor light-emitting device according to claim 1, wherein the groove portion includes a surface slanting with respect to a plane parallel to the light emission layer.

4. The semiconductor light-emitting device according to claim 2, wherein the cut portion includes a surface slanting with respect to a plane parallel to the light emission layer.

5. The semiconductor light-emitting device according to claim 2, wherein the light emission layer is displaced in a position which is displaced from the groove portion and the cut portion as viewed from another surface side of the substrate.

6. The semiconductor light-emitting device according to claim 2, wherein the light emission layer is located in a position displaced from projection regions corresponding to the groove portion and the cut portion.

7. The semiconductor light-emitting device according to claim 3, wherein the slanting surface is at an angle of 40 to 70° with respect to a normal to the light emission layer.

8. The semiconductor light-emitting device according to claim 4, wherein the slanting surface is at an angle of 40 to 70° with respect to a normal to the light emission layer.

9. The semiconductor light-emitting device according to claim 1, wherein the pair of electrodes are both provided on the surface side of the substrate.
